(19) United States
(12) Patent Application Publication
(10) Pub. No.: US 2015/0171008 A1
(43) Pub. Date: Jun. 18, 2015

(54) INTEGRATED CIRCUITS WITH DUMMY CONTACTS AND METHODS FOR PRODUCING SUCH INTEGRATED CIRCUITS

(71) Applicant: GLOBAL FOUNDRIES Singapore Pte. Ltd.

(72) Inventors: Laiqiang Luo, Singapore (SG); Jianfang Liang, Singapore (SG); Aaron Chen, Singapore (SG); Tian-Lin Chang, Singapore (SG); Fan Zhang, Singapore (SG); Juan Boon Tan, Singapore (SG)

(73) Assignee: GLOBAL FOUNDRIES Singapore Ptd. Ltd.

(21) Appl. No.: 14/109,227

(22) Filed: Dec. 17, 2013

(51) Int. Cl. H01L 23/522; H01L 21/768; H01L 21/311; H01L 23/532; H01L 21/02

(52) U.S. Cl. CPC H01L 23/5226; H01L 23/53228; H01L 23/53257; H01L 23/5329; H01L 21/02164; H01L 21/31116; H01L 21/76802; H01L 21/76877

(57) ABSTRACT

Integrated circuits with dummy contacts and methods for fabricating such integrated circuits are provided. The method includes forming an interlayer dielectric overlying an electronic component and a substrate, wherein the interlayer dielectric has an interlayer dielectric top surface. An active contact is formed through the interlayer dielectric and forms an electrical connection with the electronic component. A dummy contact is formed within the interlayer dielectric where the dummy contact extends to a dummy contact termination point between the interlayer dielectric top surface and the substrate such that an insulator is positioned between the dummy contact termination point and the electronic component.

### TECHNICAL FIELD

The technical field generally relates to integrated circuits and methods for producing integrated circuits, and more particularly relates to integrated circuits with dummy contacts and methods for producing such integrated circuits.

### BACKGROUND

Over time, integrated circuits are becoming smaller but with increased capabilities. The production of smaller integrated circuits requires the development of smaller electronic components, and closer spacing of those electronic components. In traditional integrated circuits, contacts are formed through an insulating cover layer, often called an interlayer dielectric, to form electrical connections with the underlying electronic components. Interconnects or metallization layers are then formed overlying the interlayer dielectric, where the interconnects electrically connect the electronic components in a desired manner by forming electrical connections with the contacts. There may be several layers of interconnect lines separated by interlayer dielectrics, and there may be transistors, resistors, and other electronic components separated by various other layers of interlayer dielectric as well. Many steps are required to form these components, and reducing the number of manufacturing steps can reduce the production costs.

The contacts are formed by etching a via or hole in the interlayer dielectric material, and then depositing conductive material in the via. As integrated circuits become smaller and more crowded, the tolerance for the size of the vias and contacts becomes smaller. If the via is too small, the contact will not make an electrical connection with the electronic component, and if the via is too large the contact will form a “short” and make an unwanted electrical connection to an adjacent contact area and thereby cause a failure. A plasma etchant is frequently used to form the vias, but the etch rate depends on the amount of material being etched in localized areas. Therefore, vias tend to be undersized in crowded areas, and oversized in areas where relatively few vias are etched.

Accordingly, it is desirable to develop integrated circuits with vias and contacts with smaller tolerances, and methods for producing such integrated circuits. In addition, it is desirable to develop methods for producing such integrated circuits that do not increase the number of manufacturing steps to help control production costs. Furthermore, other desirable features and characteristics of the present embodiment will become apparent from the subsequent detailed description and the appended claims, taken in conjunction with the accompanying drawings and this background.

### BRIEF SUMMARY

Integrated circuits with dummy contacts and methods for fabricating such integrated circuits are provided. In an exemplary embodiment, a method is provided for producing an integrated circuit. The method includes forming an interlayer dielectric overlying an electronic component and a substrate, wherein the interlayer dielectric has an interlayer dielectric top surface. An active contact is formed through the interlayer dielectric and forms an electrical connection with the electronic component. A dummy contact is formed within the interlayer dielectric where the dummy contact extends to a dummy contact termination point between the interlayer dielectric top surface and the substrate such that an insulator is positioned between the dummy contact termination point and the electronic component.

In another exemplary embodiment, a method for fabricating an integrated circuit includes forming an interlayer dielectric overlying an electronic components and a substrate, wherein the interlayer dielectric has an interlayer dielectric top surface. The interlayer dielectric top surface is divided into a plurality of regions including a first region and a second region. An active contact is formed within the interlayer dielectric, where the active contacts extend through the interlayer dielectric and forms an electrical connection with the electronic component, and where there are more active contacts in the first region than in the second region. A contact density variation is decreased by forming a dummy contact within the interlayer dielectric in the second region.

In a further exemplary embodiment, an integrated circuit includes an electronic component overlying a substrate. An interlayer dielectric overlays the electronic component and the substrate, where the interlayer dielectric has an interlayer dielectric top surface. An active contact extends through the interlayer dielectric and forms an electrical connection with the electronic component. A dummy contact within the interlayer dielectric extends to a dummy contact termination point between the interlayer dielectric top surface and the substrate such that an insulator separates the dummy contact from the electronic component.

### BRIEF DESCRIPTION OF THE DRAWINGS

The various embodiments will hereinafter be described in conjunction with the following drawing figures, wherein like numerals denote like elements, and wherein:

FIGS. 1-4 illustrate, in cross sectional views, a portion of an integrated circuit and methods for its fabrication in accordance with exemplary embodiments.

FIG. 5 illustrates a top view of an integrated circuit with a plurality of contacts.

### DETAILED DESCRIPTION

The following detailed description is merely exemplary in nature and is not intended to limit the application and uses of the embodiment described. Furthermore, there is no intention to be bound by any theory presented in the preceding background or the following detailed description.

Integrated circuits include many contacts that extend through an interlayer dielectric to make electrical contact with an electronic component under the interlayer dielectric. In some embodiments, the contacts are formed by anisotropically etching a via through the interlayer dielectric, and filling the via with a conductive material to form the contact. A plasma is used to etch the vias, and the etch rate of the plasma varies with the amount of material being etched locally. Therefore, a region with many vias will tend to have a slower etch rate than a region without many vias. The variation in the etch rate increases the variation in the contact size, which increases manufacturing tolerances. The current description contemplates the use of dummy contacts positioned in regions with low concentrations of contacts, so the total amount of material being etched is more consistent from one region to the next. This produces a more uniform and consistent via etch rate over the entire interlayer dielectric, which results in smaller tolerances for the contact vias. The dummy contacts are positioned over shallow trench isolation areas or other areas such that the dummy contacts are not electrically connected to electrical components and thereby do not affect the operation of the integrated circuit.

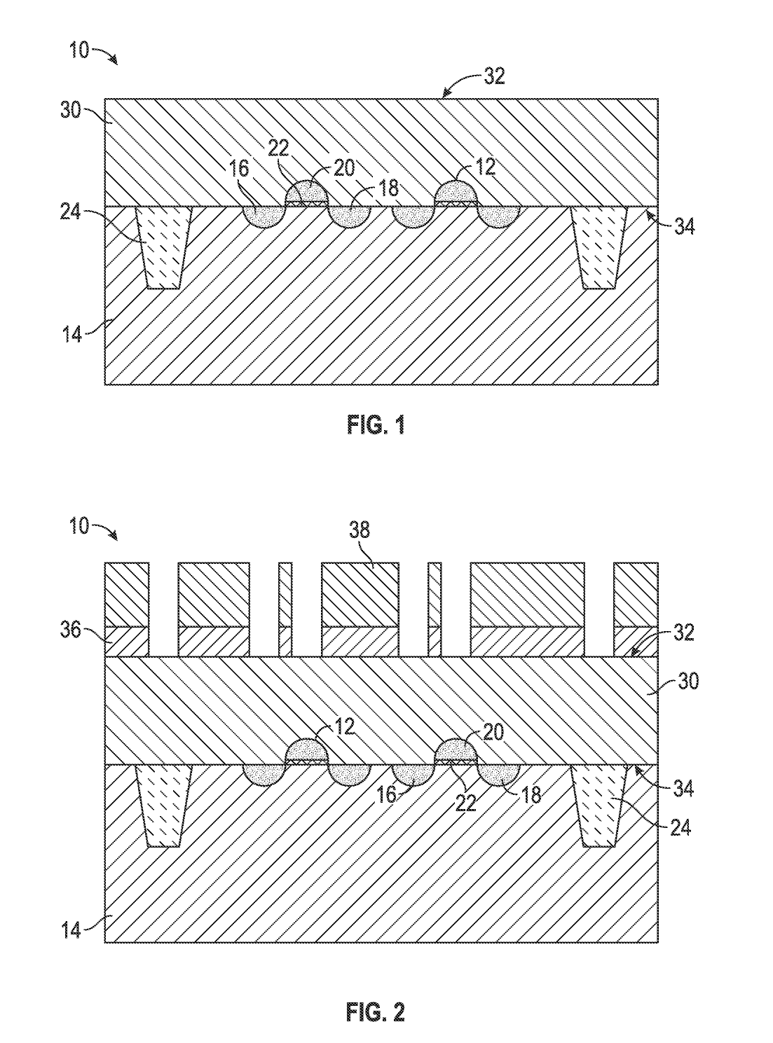

Referring to FIG. 1, in accordance with an exemplary embodiment, an integrated circuit 10 includes a plurality of electronic components 12 overlying a substrate 14. As used herein, the term “overlying” means “over” such that an intervening layer may lie between the electronic components 12 and the substrate 14, and “on” such that the electronic components 12 physically contact the substrate 14. As used herein, the term “substrate” 14 will be used to encompass semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. Semiconductor materials also include other materials such as relatively pure and impurity-doped germanium, gallium arsenide, zinc oxide, glass, and the like. In an exemplary embodiment, the semiconductor material is a monocrystalline silicon substrate. The silicon substrate may be a bulk silicon wafer (as illustrated) or may be a thin layer of semiconductor on an insulating layer (commonly known as semiconductor-on-insulator or SOI) that, in turn, is supported by a carrier wafer.

A wide variety of electronic components 12 can be used. A partial list of potential electronic components 12 includes various types of transistors, resistors, capacitors, etc. FIG. 1 illustrates, in an exemplary embodiment, a field effect transistor with a source 16, a drain 18, and a gate 20 overlying a gate insulator 22. However, other types of electronic components 12 are also possible. Electrical connections are often made to more than one location on a single electronic component 12. For example, in some integrated circuits electrical connections are made to the source 16, the drain 18, and/or the gate 20 of many transistors. Electronic components 12 are produced by a wide variety of methods, and the means of production of the electronic components are not critical to this description. A variety of different types of electronic components 12 are included in many integrated circuits, so one integrated circuit will include several different types of electronic components 12.

In some embodiments, a shallow trench isolation 24 is formed within the substrate, where the shallow trench isolation 24 is formed of an insulating material such as silicon dioxide, silicon nitride, silicon oxynitride, or other insulating materials. The shallow trench isolation 24 may be completely embedded in the substrate 14, it may be recessed, or it may extend above the upper surface of the substrate 14 in various embodiments.

An interlayer dielectric 30 is formed overlying the substrate 14, the electronic components 12, and the shallow trench isolation 24. The interlayer dielectric 30 is an insulating material that covers the electronic components 12, substrate 14, and shallow trench isolation 24. In an exemplary embodiment, the interlayer dielectric 30 is silicon oxide, which can be deposited by chemical vapor deposition using tetraethylorthosilicate (TEOS). In alternate embodiments, other deposition techniques are used, and other insulating materials can also be used, including but not limited to silicon nitride or silicon oxynitride. The interlayer dielectric 30 has an interlayer dielectric top surface 32 remote from the substrate 14, and an interlayer dielectric bottom surface 34 opposite the interlayer dielectric top surface 32 and adjacent the substrate 14, electronic components 12, and the shallow trench isolation 24.

Reference is now made to FIG. 2. In an exemplary embodiment, an optional hard mask 36 is formed overlying the interlayer dielectric 30. The hard mask 36 is formed of silicon nitride, which can be deposited by low pressure chemical vapor deposition using ammonia and dichlorosilane. A photoresist layer 38 is formed overlying the hard mask 36 and the interlayer dielectric 30, and the photoresist layer 38 is patterned and developed to expose selected locations. The photoresist layer 38 is deposited by spin coating, and patterned by exposure to light or other electromagnetic radiation through a mask with transparent sections and opaque sections. The light causes a chemical change in the photoresist such that either the exposed portion or the non-exposed portion can be selectively removed. Selected locations of the photoresist layer 38 are removed with an organic solvent, and remaining portions of the photoresist layer 38 overlie other areas of the hard mask 36 and interlayer dielectric 30. Using the photoresist layer 38 as an etch mask, the hard mask 36 then is etched exposing portions of the interlayer dielectric 30. A hard mask 36 formed of silicon nitride can be etched with a plasma etch using nitrogen trifluoride in a hydrogen ambient.

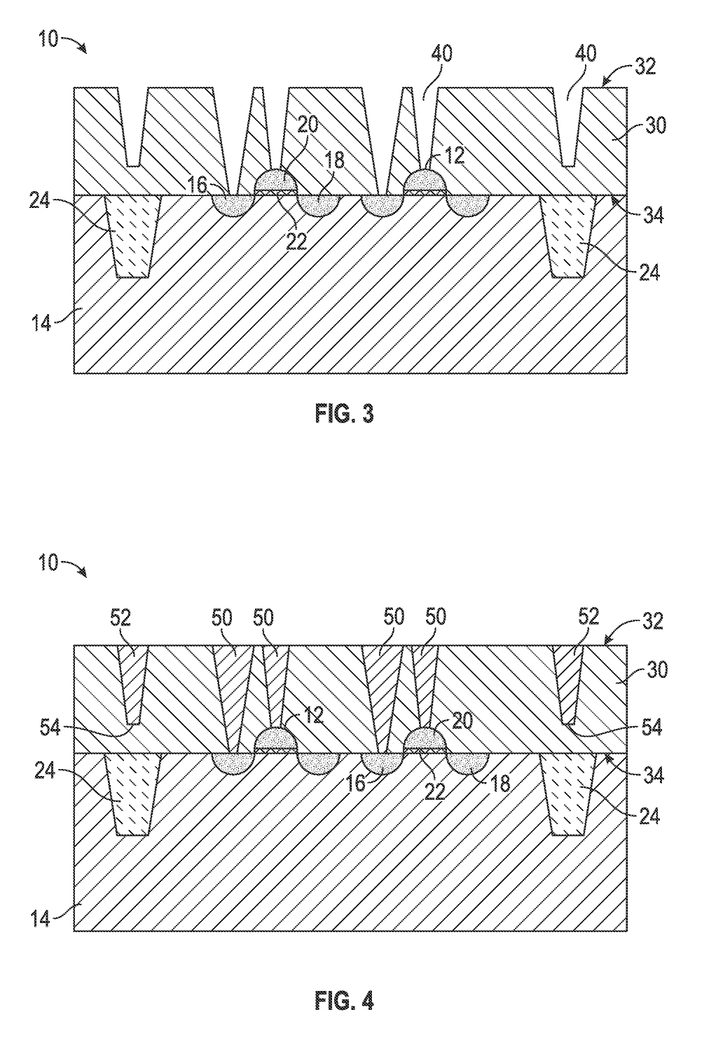

Next a plurality of vias 40 are formed through the interlayer dielectric 30, as illustrated in FIG. 3 with continuing reference to FIG. 2. The vias 40 are formed by an anisotropic etch, and in some embodiments the etchant is selective to the material of the interlayer dielectric 30 over the material of the substrate 14. The etchant is also selective to the material of the interlayer dielectric 30 over the material of the electronic component 12, so the via 40 will terminate on the surface of the electronic component 12. In an exemplary embodiment, the interlayer dielectric 30 is silicon dioxide, the substrate 14 is monocrystalline silicon, and a plasma etch is used. There are many plasma etchants that are selective to silicon dioxide over monocrystalline or polycrystalline silicone, such as: (a) acetylene and hydrogen; (b) trifluoromethane; (c) ammonia and trifluoro nitrogen in a hydrogen and nitrogen atmosphere; (d) tetrafluoro methane and oxygen in a hydrogen and nitrogen atmosphere; and (e) tetrafluoro methane and hydrogen. The photoresist layer 38 may be removed before or after the via 40 is formed in various embodiments, where the patterned hard mask 36 is in place in embodiments where the photoresist layer 38 is removed before the etch.

The vias 40 are filled with conductive materials to form a plurality of contacts, including active contacts 50 and dummy contacts 52, as illustrated in FIG. 4. In an exemplary embodiment, the active and dummy contacts 50, 52 include an adhesion layer, a barrier layer, and a plug (not separately shown), which are sequentially deposited. For example, an adhesion layer of titanium is formed by low pressure chemical vapor deposition of titanium pentachloride, a barrier layer of titanium nitride is formed by chemical vapor deposition of titanium tetrabromide and ammonia, and a plug of tungsten is formed by chemical vapor deposition of tungsten hexafluoride and hydrogen. Other types of contacts are also possible, such as copper or other conductive materials. Copper active and dummy contacts 50, 52 can be formed using known damascene processes.

The active contacts 50 are formed in the interlayer dielectric 30, and extend through the interlayer dielectric 30 from the interlayer dielectric top surface 32 to make an electrical connection with an electronic component 12. The dummy contacts 52 are also formed in the interlayer dielectric 30 and extend from the interlayer dielectric top surface 32 to a dummy contact termination point 54. The dummy contacts 52 terminate within the interlayer dielectric 30. In this regard, an insulating material is between the dummy contact termination point 54 and an electronic component 12. The insulating material prevents the dummy contact 52 from forming an electrical connection with the electrical component 12. In many embodiments, the dummy contact 52 is aligned with the shallow trench isolation 24 such that any over-extension of the dummy contact 52 does not make an electrical contact with an electronic component 12 and instead leaves the dummy contact termination point 54 overlying the shallow trench isolation 24. In alternate embodiments, an insulating material (not shown) can be deposited on the substrate 14 as an etch stop for the dummy contact 52, so the dummy contact termination point 54 is at the interface of the deposited insulating material and the interlayer dielectric 30. For example, silicon nitride can be deposited as an etch stop, where the etchant is selective to silicon dioxide in the interlayer dielectric 30 over the silicon nitride etch stop.

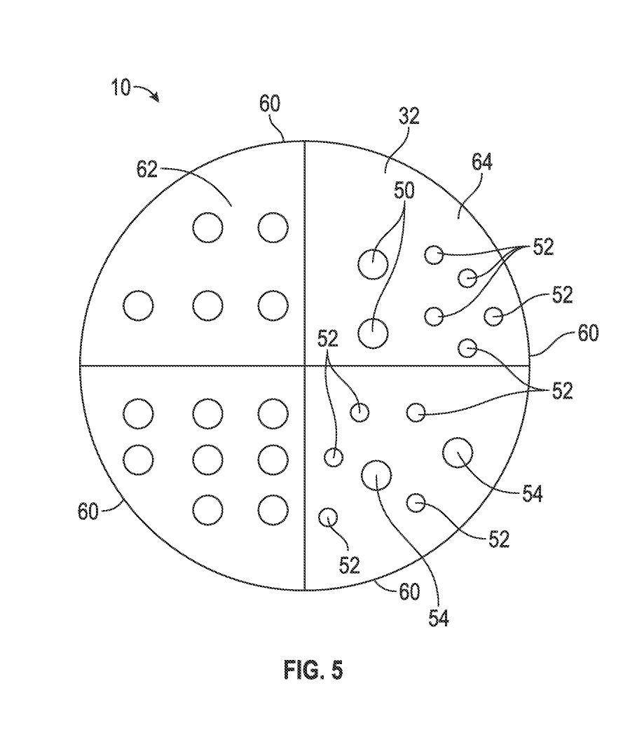

Reference is now made to FIG. 5, with continuing reference to FIGS. 3 and 4. FIG. 5 is a top view of one embodiment showing an interlayer dielectric top surface 32 with a plurality of active contacts 50 and dummy contacts 52, and FIG. 4 is a cross sectional view of a portion of an interlayer dielectric 30 with contacts and electrical components. The interlayer dielectric top surface 32 is divided into a plurality of regions 60, where each region 60 has a known surface area and a known number of active contacts 50. For example, a first region 62 has a set area and has more active contacts 50 than a second region 64 that has the same set area. A contact density can be calculated for each region 60, where the contact density is a total contact surface area divided by a region surface area. The surface area of one contact is referred to as the contact surface area, so the total contact surface area is the sum of the contact surface areas of all the active and dummy contacts 50, 52 within a region 60. In some embodiments, the active contacts 50 are positioned in such a way that the contact density varies from one region 60 to the next, so there is a variable contact density. The position of the active contacts 50 is determined by the design of the integrated circuit 10, and some designs concentrate the active contacts 50 in one or more regions 60 relative to other regions 60. One or more dummy contact(s) 52 can be formed in a region 60 with a lower density of active contacts 50 (based on the design of the integrated circuit 10), and this will increase the contact density for that region. In this manner, the contact density variation is reduced by forming dummy contacts 52 in regions that have fewer active contacts 52 per area, such as the second region 64 relative to the first region 62. The reduced variation in the contact density improves the consistency of the plasma etch rate in the different regions 60, which results in more consistently sized active and dummy contacts 50, 52, as described above.

In an exemplary embodiment, the interlayer dielectric 30 is primarily silicon dioxide, the shallow trench isolation 24 is also primarily silicon dioxide, and the substrate 14 is primarily monocrystalline silicon. The dummy contact 52 is aligned with the shallow trench isolation 24, which means the dummy contact 52 is positioned directly over the shallow trench isolation 24 and extends downward into the interlayer dielectric 30 toward the shallow trench isolation 24. The plasma etchant is selective to silicon dioxide over silicon, but the interlayer dielectric 30 and the shallow trench isolation 24 are both the same material; silicon dioxide. Therefore, the etch rate will not slow if the via 40 for the dummy contact 52 completely penetrates the interlayer dielectric 30 and enters the shallow trench isolation 24. If the etch was continued for too long, the via 40 and resulting dummy contact 52 would extend through the shallow trench isolation 24 and make contact with the substrate 14 underneath. In such a case, current could flow through the dummy contact 52 to the substrate 14 underlying the shallow trench isolation 24, which would adversely affect the operation of the integrated circuit 10. Therefore, it is desirable to limit the depth of the vias designated for dummy contacts 52 such that the vias 40 terminate short of the shallow trench isolation 24.

In an exemplary embodiment, the depths of the vias 40 for the dummy contacts 52 are limited by decreasing a dummy contact surface area relative to an active contact surface area. As seen in FIG. 5, the surface area of each of the dummy contacts 52 is less than the surface area of each of the active contacts 50. The surface area of the active contacts 50 and the dummy contacts 52 is determined by the patterning of the photoresist layer 38, and the subsequent etch forms the vias 40 for both the active and dummy contacts 50, 52, so no extra manufacturing processes are required to produce the dummy contacts 52. A smaller gap is produced in the photoresist layer 38 for the dummy contacts 52, which reduces the area the etchant has to access the dummy contact via 40 during the etching process. Providing a dummy contact surface area for each dummy contact 52 that is from about 70 to about 80 percent of the active contact surface area for each active contact 50 can produce a dummy contact 52 that extends into the interlayer dielectric, but does not penetrate the interlayer dielectric bottom surface 34 such that the dummy contact termination point 54 is within the interlayer dielectric 30. Reducing the size of the dummy contact surface area relative to the size of the active contact surface area can prevent the dummy contact 52 from extending into and through the shallow trench isolation 24 and forming an electrical connection with the substrate 14.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the application in any way. Rather, the foregoing detailed description will provide those skilled in the art with a convenient road map for implementing one or more embodiments, it being understood that various changes may be made in the function and arrangement of elements described in an exemplary embodiment without departing from the scope, as set forth in the appended claims.

What is claimed is:

1. A method of producing an integrated circuit comprising:
forming an interlayer dielectric overlying an electronic component and a substrate, wherein the interlayer dielectric has an interlayer dielectric top surface remote from the substrate;
forming an active contact through the interlayer dielectric, wherein the active contact forms an electrical connection with the electronic component; and
forming a dummy contact within the interlayer dielectric wherein the dummy contact extends to a dummy contact termination point between the interlayer dielectric top surface and the substrate, and wherein an insulator is positioned between the dummy contact termination point and the electronic component.

2. The method of claim 1 wherein:
forming the interlayer dielectric further comprises forming the interlayer dielectric overlying a shallow trench isolation within the substrate; and
forming the dummy contact within the interlayer dielectric further comprises forming the dummy contact aligned with the shallow trench isolation.

3. The method of claim 2 wherein:
forming the dummy contact further comprises forming the dummy contact such that the dummy contact termination point is within the interlayer dielectric.

4. The method of claim 1 further comprising:
forming a plurality of vias in the interlayer dielectric with a plasma etch, wherein the active contact and the dummy contact are formed within the plurality of vias.

5. The method of claim 4 wherein:
forming the interlayer dielectric further comprises forming the interlayer dielectric from silicon dioxide; and
wherein forming the via further comprises etching the interlayer dielectric with the plasma etch, wherein the plasma etch is selective to silicon dioxide over silicon.

6. The method of claim 1 wherein:
forming the active contact further comprises forming the active contact with an active contact surface area; and
forming the dummy contact further comprises forming the dummy contact with a dummy contact surface area that is less than the active contact surface area.

7. The method of claim 6 wherein forming the dummy contact further comprises forming the dummy contact wherein the dummy contact surface area for each dummy contact is from about 70 percent to about 80 percent of the active contact surface area for each active contact.

8. The method of claim 1 further comprising:
dividing the interlayer dielectric top surface into a plurality of regions, wherein each region has a region surface area; and
positioning the dummy contact such that a contact density variation in the plurality of regions is decreased.

9. The method of claim 1 wherein forming the active contact further comprises forming the active contact wherein the active contact comprise copper.

10. A method of producing an integrated circuit comprising:
forming an interlayer dielectric overlying an electronic component and a substrate, wherein the interlayer dielectric has an interlayer dielectric top surface;
dividing the interlayer dielectric top surface into a plurality of regions, wherein the plurality of regions includes a first region and a second region;
forming an active contact within the interlayer dielectric wherein the active contact extends through the interlayer dielectric and forms an electrical connection with the electronic component, and wherein the active contact is formed such that the first region has more active contacts than the second region; and
decreasing a contact density variation in the plurality of regions by forming a dummy contact within the interlayer dielectric in the second region.

11. The method of claim 10 wherein forming the dummy contact further comprises forming the dummy contact such that the dummy contact extends from the interlayer dielectric top surface to a dummy contact termination point, and wherein an insulator is positioned between the electronic component and the dummy contact termination point.

12. The method of claim 11 wherein forming the dummy contact further comprises forming the dummy contact such that the dummy contact termination point is within the interlayer dielectric.

13. The method of claim 10 wherein:
forming the interlayer dielectric further comprises forming the interlayer dielectric overlying a shallow trench isolation; and
forming the dummy contact further comprises forming the dummy contact aligned with the shallow trench isolation.

14. The method of claim 10 wherein forming the active contact further comprises forming the active contact wherein the active contact comprises copper.

15. The method of claim 10 wherein:
forming the active contact further comprises forming the active contact wherein each active contact has an active contact surface area; and
forming the dummy contact further comprises forming the dummy contact wherein each dummy contact has a dummy contact surface area that is less than the active contact surface area.

16. The method of claim 15 wherein forming the dummy contact further comprises forming the dummy contact wherein the dummy contact surface area for each dummy contact is from about 70 percent to about 80 percent of the active contact surface area for each active contact.

17. The method of claim 10 wherein forming the active contact further comprises forming the active contact wherein the active contact comprises titanium.

18. The method of claim 10 further comprising:
forming a plurality of vias in the interlayer dielectric with a plasma etch, wherein the active contact and the dummy contact are formed within the plurality of vias.

19. The method of claim 18 wherein:
forming the interlayer dielectric further comprises forming the interlayer dielectric from silicon dioxide; and
wherein forming the via further comprises etching the interlayer dielectric with the plasma etch, wherein the plasma etch is selective to silicon dioxide over silicon.

20. An integrated circuit comprising:
a substrate;
an electronic component overlying the substrate;
an interlayer dielectric overlying the electronic component and the substrate, wherein the interlayer dielectric has an interlayer dielectric top surface opposite the substrate;
an active contact within the interlayer dielectric, wherein the active contact extends through the interlayer dielectric and forms an electrical connection with the electronic component; and
a dummy contact within the interlayer dielectric, wherein the dummy contact extends to a dummy contact termination point between the interlayer dielectric top surface and the substrate, and wherein an insulator separates the dummy contact termination point from the electronic component.
